(19) United States
(12) Patent Application Publication
(10) Pub. No.: US 2024/0020431 A1
(43) Pub. Date: Jan. 18, 2024

(54) CONNECTION DESIGN METHOD FOR LATERAL RESISTING SYSTEM OF SELF-CENTERING STEEL FRAME

(71) Applicants: CHINA RAILWAY FIRST GROUP BUILDING & INSTALLATION ENGINEERING CO.,LTD., Xi'an (CN); CHINA RAILWAY FIRST GROUP CO., LTD, Xi'an (CN); HAINAN UNIVERSITY, Haikou (CN)

(72) Inventors: Yun Chen, Haikou (CN); Hailiang Zhang, Xi'an (CN); Bicheng Zhou, Haikou (CN); Baoping Wang, Xi'an (CN); Fengchao Zhang, Xi'an (CN); Huabing Xiong, Xi'an (CN); Donglei Yang, Xi'an (CN); Longgang Lei, Xi'an (CN)

(21) Appl. No.: 18/361,821

(22) Filed: Jul. 29, 2023

(30) Foreign Application Priority Data
Apr. 21, 2023 (CN) 202310434483.5

(51) Int. Cl. G06F 30/13

(52) U.S. Cl. CPC G06F 30/13; E04H 9/024

(57) ABSTRACT

The present invention discloses a connection design method for a lateral resisting system of a self-centering steel frame, comprising: determining basic sizes and performance parameters of a steel frame, a connection design load, the performance targets of connections and an inter-storey drift angle limit, calculating an inter-storey lateral drift limit, the rotational stiffness of a beam column connection and a column base connection and the angular drift limits of the beam column connection and the column base connection, designing the section size of an energy dissipation steel plate, calculating an allowable bending moment of a column bottom and an allowable bending moment of the beam column connection, an axial force of anchor rod and the axial force of a beam column and the local pressure of each flange when the column bottom reaches angular drift limits, conducting strength checking, stability checking and local pressure checking, and checking self-centering capability.

### TECHNICAL FIELD

The present invention relates to the technical field of earthquake resistance of civil engineering, and in particular to a connection design method for a lateral resisting system of a self-centering steel frame.

### BACKGROUND

When natural disasters occur, earthquakes and typhoons mainly stimulate the structure in a horizontal direction. Thus, a lateral resisting system which mainly resists the horizontal load becomes the most critical link to protect the safety of the structure. The lateral resisting system is arranged, which not only can ensure that the structure meets the requirements of stiffness, strength and ductility in normal use and bearing capacity limit states, but also can give full play to the performance of materials and obtain good economic benefits.

In the existing lateral resisting system of a self-centering frame, a frame structure is formed generally by a foundation, steel columns and cross beams. For example, application publication number CN111691544A (application publication date 2020 Sep. 22) discloses a lateral resisting system of a self-centering steel frame, comprising a self-centering column base structure and a self-centering connection structure. The steel columns are vertically arranged on the top surface of the foundation, and the bottom ends of the steel columns are connected with the foundation to form the self-centering column base structure. A steel plate is embedded inside the foundation. A suspension board is horizontally fixed on the side wall of the steel column. The anchor rod passes through the suspension board and the embedded steel plate, and are fixed through first high strength nuts. A first disc spring group is sleeved between the first high strength nuts and the top end of the top surface of the suspension board. The cross beams are arranged horizontally, and the ends of the cross beams are connected with the side walls of the steel columns to form a self-centering connection structure. End plates are fixed at the ends of the cross beams, and high strength pull rods pass through the side walls of the cross beams and the end plates, and are fastened by second high strength nuts. A second disc spring group is fixed between the end plate of at least one end of the high strength pull rods and the second high strength nuts. Stiffening ribs are arranged up and down between the high strength pull rods. Both ends of a C-type energy dissipation steel plate are fixedly connected with the side walls of the steel columns and the flanges of the cross beams respectively. The principle is that, in an earthquake, when the cross beams swing, the earthquake energy can be dissipated in the earthquake by the C-type energy dissipation steel plates between the beams and the columns; when the cross beams swing up and down, the deformation of the second disc spring group on the plurality of groups of high strength pull rods connected with the beams and the columns is increased, so as to realize the rapid post-earthquake self-centering of the frame structure; and finally, the energy dissipation and self-centering function of the beam column connections are realized, which solves the problem of large residual deformation of the beams and the columns after the earthquake, and enables the structure to dissipate energy in the earthquake and quickly restore the use function after the earthquake.

At present, the traditional earthquake resistance thought takes the protection of life as the primary goal, and avoids the collapse of the structure under strong earthquakes through ductility design. However, the ductility design comes at the cost of allowing plastic deformation of the main stressed members of the structure. On the other hand, due to the uncertainty of earthquake action, the structure may suffer stronger earthquake action than fortification intensity during use and is seriously damaged or even overturned. The results of earthquake disasters in recent years show that although the number of building collapses and human deaths in earthquakes has been effectively controlled, the direct and indirect economic losses caused by the earthquakes are huge, wherein the indirect economic losses caused by the interruption of urban functions have exceeded the direct economic losses. In recent years, many researchers have proposed the concept of recoverable functional structure. Earthquake recoverable functional structure refers to the structure that can restore the use function without repair or with slight repair after an earthquake. Its main purpose is to enable the structure to have the capability of quickly recovering the use function after the earthquake, so as to reduce the impact caused by the interruption of the structure functions after the earthquake.

Therefore, it is an urgent problem for those skilled in the art to propose a connection design method for a lateral resisting system of a self-centering steel frame with strong horizontal load resistance, self-centering performance, energy dissipation capacity and excellent ductility and fatigue resistance.

### SUMMARY

In view of this, the present invention provides a connection design method for a lateral resisting system of a self-centering steel frame to solve the above technical problems.

To realize the method design provided by the present invention, firstly, the present invention provides a corresponding lateral resisting system of a self-centering steel frame, comprising: a foundation, steel columns and cross beams;

The steel columns are vertically arranged on the top surface of the foundation, and the bottom ends of the steel columns are connected with the foundation to form a self-centering column base structure;

The cross beams are horizontally arranged, and ends are connected with the side walls of the steel columns; and the steel columns and the cross beams connected at both sides form a self-centering connection structure.

When the system provided by the present invention is under the action of frequently occurred earthquakes, each connection of the structure is closed, which is consistent with the traditional structure, to resist the action of the earthquakes relying on the elastic deformation of the structure. Under the action of rarely occurred earthquakes, each connection of the structure is opened to prevent a main structure from generating plastic loss. Meanwhile, the self-centering column base structure, a self-centering connection structure and an energy dissipation device generate plastic deformation to dissipate seismic energy, to jointly ensure that the connections and the column base have good self-centering performance and the lateral resistance, energy dissipation and self-centering functions of the whole system can be finally realized.

Preferably, in the above lateral resisting system of a self-centering steel frame, the self-centering column base structure comprises an embedded steel plate, a suspension board, anchor bolts and a first disc spring group;

The embedded steel plate is embedded inside the foundation.

The suspension board is horizontally fixed to the side wall of the steel column near the foundation.

A plurality of anchor rods are arranged, and are vertically distributed; both ends of the anchor rods pass through the suspension board and the embedded steel plate respectively, and are fastened through first high strength nuts.

The first disc spring group is sleeved at the top ends of the anchor rods, and abutted between the top surface of the suspension board and the first high strength nuts at the top end.

The structure swings; the suspension board at the bottom of the steel columns tilts and presses the first disc spring group; and the first disc spring group produces a reaction force to compel the structure to return to an initial position, thereby achieving the effect of self-centering the column base structure. Meanwhile, due to the limitation of the first high strength nuts on the first disc spring group, the maximum swing position of the structure is limited by the heights of the first high strength nuts, which increases the swing controllability.

Preferably, in the above lateral resisting system of a self-centering steel frame, the top surface of the foundation is provided with a limiting groove through which the steel columns are inserted; a bottom plate is fixed at the bottom ends of the steel columns; and a cushioning rubber pad is fixed between the bottom plate and the limiting groove. The cushioning rubber pad arranged at the bottom end of the steel column can play a cushioning role in the earthquake, and the limiting groove controls the lateral drift at the bottom of the steel column.

Preferably, in the above lateral resisting system of a self-centering steel frame, a supporting plate is fixed between the bottom surface of the suspension board and the side wall of the steel column. The structural stability of the suspension board can be effectively improved.

Preferably, in the above lateral resisting system of the self-centering steel frame, the self-centering connection structure comprises end plates, high strength pull rods and C-type energy dissipation steel plates;

The end plates are fixed to the ends of the cross beams;

A plurality of high strength pull rods are arranged, horizontally penetrate through the side walls of the steel columns and the two end plates, and are fastened at both ends through second high strength nuts. and at least one end of the high strength pull rods is sleeved with a second disc spring group abutted between the end plates and the second high strength nuts;

A plurality of C-type energy dissipation steel plates are arranged; and both ends of the C-type energy dissipation steel plates are fixedly connected with the side walls of the steel columns and flanges of the cross beams respectively.

In an earthquake, when the cross beams swing, the earthquake energy can be dissipated in the earthquake by the C-type energy dissipation steel plates between the beams and the columns; when the cross beams swing up and down, the deformation of the second disc spring group on the plurality of groups of high strength pull rods connected with the beams and the columns is increased, so as to realize the rapid post-earthquake self-centering of the frame structure; and finally, the energy dissipation and self-centering function of the beam column connections are realized, which solves the problem of large residual deformation of the beams and the columns after the earthquake, and enables the structure to dissipate energy in the earthquake and quickly restore the use function after the earthquake.

Preferably, in the above lateral resisting system of the self-centering steel frame, in the self-centering connection structure, a plurality of stiffening ribs are welded and fixed between two side walls of the steel columns, and the stiffening ribs are arranged up and down between the high strength pull rods. The strength of the side walls of the steel columns is improved.

Preferably, in the above lateral resisting system of the self-centering steel frame, the highest layout horizontal plane of the plurality of stiffening ribs is flush with the top surface of the cross beams, and the lowest layout horizontal plane is flush with the bottom surface of the cross beams. The strength of the steel columns can be improved, and the structural strength of connection between the steel columns and the cross beams can also be improved.

Preferably, in the above lateral resisting system of the self-centering steel frame, both ends of the C-type energy dissipation steel plates are welded and fixed with the side walls of the steel columns and the flanges of the cross beams, or fixed with bolts respectively. The C-type energy dissipation steel plates can in non-permanent connection easy for replacement and maintenance, or in stable permanent connection.

Preferably, in the above lateral resisting system of the self-centering steel frame, the steel columns are I-steel or square steel tubes or concrete filled steel tubes. The use range of the structure of the present invention can be extended.

Based on the structure of the above lateral resisting system of the self-centering steel frame, to achieve the above connection design, the present invention adopts the following technical solution:

A connection design method for a lateral resisting system of a self-centering steel frame comprises the following steps:
step 1: determining basic dimension parameters and material characteristics of components of a steel frame;
step 2: determining a connection design load;
step 3: determining the performance targets of a connection;
step 4: determining an inter-storey drift angle limit θ under the action of a rare earthquake and calculating an inter-storey lateral drift limit Δ;
step 5: calculating the rotational stiffness of a beam column connection and a column base connection;
step 6: calculating the angular drift limits of the beam column connection and the column base connection according to a force method or a drift method;
step 7: designing the section size of a C-type energy dissipation steel plate;
step 8: calculating an allowable bending moment of a column bottom and an allowable bending moment of the beam column connection under the action of the rare earthquake;
step 9: calculating an axial force of a pull rod when the angular drift limits are reached;
step 10: calculating the axial force of a beam column and the local pressure of each flange when the column bottom reaches the angular drift limits;
step 11: conducting strength checking, stability checking and local pressure checking;
step 12: checking self-centering capability.

Through the above technical solution, in the connection design method for the lateral resisting system of the self-centering steel frame provided by the present invention, structural components are independent in functions, clear in stress and definite in force transmission. The vertical load of the main structure is mainly borne by the prepressure provided by the disc springs, which is different from the traditional energy-dissipating angle steel which bears both shear resistant and energy dissipation purposes. The C-type energy dissipation steel plates are easy to deform under the stress and do not increase the bearing capacity and shearing resistance, which is convenient for the calculation of the stress of the main structure. The checking of the bearing capacity and the stability under the action of large earthquakes is conducted on the basis of meeting the requirements of small earthquakes. The calculation methods are simple and feasible, can ensure more accurate results, and have good popularization and application values. The lateral resisting system of the steel frame designed by the method has strong resistance to horizontal load, self-centering performance and energy dissipation capability, and also has excellent ductility and fatigue resistance.

Preferably, in the above connection design method for the lateral resisting system of the self-centering steel frame, in step 1, the section sizes and heights of steel columns and steel beams are determined, and the used steel has sectional inertia moment I, elastic modulus E and yield strength f_{y}. This is used as the calculation basis of connection design.

Preferably, in the above connection design method for the lateral resisting system of the self-centering steel frame, in step 2, the shearing force of the column bottom is resisted by embedding shear keys in the foundation, and the shear keys only constrain the horizontal lateral movement of the column base. After consideration, the elastic effect of the structure is calculated under the action of small earthquakes, and then the design internal force required by each connection is obtained through the combination of load effects.

Preferably, in the above connection design method for the lateral resisting system of the self-centering steel frame, in step 3, the prepressure F₀ to be applied for each anchor rod at the column bottom is determined according to the performance-based design requirements in the current seismic codes, so that the flanges of the column base are not separated from the foundation under the action of small earthquakes; and prepressure F₀′ to be applied for the beam column connection is determined so that beam flanges are not separated from the side walls of the columns under the action of small earthquakes.

The bending moment M at the column bottom under the action of small earthquakes is known from the above calculation of the internal force. In order to prevent the column base from lifting, the bending moment value generated by the prepressure and the axial force on the rotation point of the column base shall be greater than the bending moment M at the column bottom under the action of small earthquakes, namely:

N×0.5 h+M₀≥M;

The beam end bending moment Mt under the action of small earthquakes is known. In order to keep the beam column connection closed, the bending moment value generated by the prepressure on the rotation point of the beam column connection shall be greater than the bending moment Mt at the column top under the action of small earthquakes, namely:

M₀′≥Mₜ

M₀ is the bending moment value generated by the prepressure on the rotation point of the column base, M₀′ is the bending moment value generated by the prepressure on the rotation point of the beam column connection and h is the sectional height of the column. Since the axial force is known, the prepressure F₀ of each anchor rod can be calculated.

Preferably, in the above connection design method for the lateral resisting system of the self-centering steel frame, in step 4, an inter-storey drift angle limit θ in a large earthquake is determined according to the current building seismic design code of China, and then an inter-storey lateral drift limit Δ is calculated.

When the angle is very small, tanx=x, so Δ/h_{c}=θ; h_{c} is the column height, and h_{c} and θ are both known, so Δ can be obtained.

Preferably, in the above connection design method for the lateral resisting system of the self-centering steel frame, in step 5, the rotational stiffness K₁′ of the column top and the rotational stiffness K₂′ of the column base generated by the disc spring and energy dissipating parts are obtained by taking the moment of the rotation point; K₁′ and K₂′ are not considered, and the column bottom is set as hinged. The upper column generates rotational stiffness K₁″=3.5i₂ to point A; point A provides rotational stiffness for point B: K₂″=αi₁; α is rotational constraint stiffness coefficient, and i₁ is column line stiffness, wherein:

$$\{ \begin{matrix}α = \frac{28 \times ( {i}_{1} + {i}_{2} ) - 4 \times {i}_{1}}{7 \times ( {i}_{1} + {i}_{2} ) + {i}_{1}} \\ {i}_{1} = \frac{E \times I}{{h}_{c}}\end{matrix}$$

Horizontal lateral movement weakens rotational stiffness transfer. Kₜ and K_{d} are the rotational stiffness at both ends of the column. The lateral stiffness D of the column top can be calculated, and then the rotational stiffness K₁″′ transferred by K₂′ to the column top and rotational stiffness K₂′″ transferred by K₁′ to the column bottom can be obtained. Thus, rotational stiffness of the column base can be obtained: K₂=K₂′+K₂″+K₂″′, and rotational stiffness of the column top is K₁=K₁′+K₁″+K₁″′, wherein:

$$\{ \begin{matrix}D = \sum {D}_{J} ; {D}_{J} = \frac{12 i}{{l}^{2}} ( \frac{{K}_{t} {K}_{d} + i ( {K}_{t} + {K}_{d} )}{{K}_{t} {K}_{d} + 4 i ( {K}_{t} + {K}_{d} ) + 12 {i}^{2}} ) \\ {K}_{1}^{′′′} = 4 i ( \frac{D \times {K}_{2}^{′} \times {h}_{c}^{2} + 3 i \times {K}_{2}^{′} + 3 i \times D \times {h}_{c}^{2}}{D \times {K}_{2}^{′} \times {h}_{c}^{2} + 4 i \times D \times {h}_{c}^{2} + 12 {i}^{2} + 3 i \times {K}_{2}^{′}} ) \\ {K}_{2}^{′′′} = 4 i ( \frac{{K}_{1}^{′} + 3 i}{{K}_{1}^{′} + 4 i} ) \\ {K}_{1} = {K}_{1}^{′} + {K}_{1}^{″} + {K}_{1}^{′′′} \\ {K}_{2} = {K}_{2}^{′} + {K}_{2}^{″} + {K}_{2}^{′′′}\end{matrix}$$

Preferably, in the above connection design method for the lateral resisting system of the self-centering steel frame, in step 6, the inter-storey lateral drift limit Δ in a large earthquake is determined in step 4; and the angular drift limits θ₁ and θ₂ of the beam column connection and the column base connection are calculated according to a force method or a drift method.

The rotational stiffness K₁ and K₂ at both ends of the column, the horizontal lateral movement at the column top and the column body line stiffness i₁ are known, and equations of the force method are listed:

$$\{ \begin{matrix}{δ}_{11} {X}_{1} + {δ}_{12} {X}_{2} + \frac{Δ}{{h}_{c}} = - \frac{{X}_{1}}{{K}_{1}} \\ {δ}_{21} {X}_{1} + {δ}_{22} {X}_{2} + \frac{Δ}{{h}_{c}} = - \frac{{X}_{2}}{{K}_{2}}\end{matrix} \\ ( {X}_{1} and {X}_{2} directions are assumed as clockwise ) \\ \{ \begin{matrix}{δ}_{11} {X}_{1} + {δ}_{12} {X}_{2} - \frac{Δ}{{h}_{c}} = - \frac{{X}_{1}}{{K}_{1}} \\ {δ}_{21} {X}_{1} + {δ}_{22} {X}_{2} - \frac{Δ}{{h}_{c}} = - \frac{{X}_{2}}{{K}_{2}}\end{matrix} \\ ( {X}_{1} and {X}_{2} directions are assumed as anti - clockwise )$$

Bending moments X₁ and X₂, at the column top and the column bottom can be calculated, and then angles θ₁ and θ₂ at the column top and the column bottom can be calculated.

A drift method is also used for checking results:

$$\{ \begin{matrix}4 i {θ}_{1} + 2 i {θ}_{2} + \frac{6 i}{{h}_{c}} Δ = - {k}_{1} {θ}_{1} \\ 4 i {θ}_{2} + 2 i {θ}_{1} + \frac{6 i}{{h}_{c}} Δ = - {k}_{2} {θ}_{2}\end{matrix} ;$$

The results are consistent, and the angular drift limits θ₁ and θ₂ of the beam column connection and the column base connection in the large earthquake are obtained.

Preferably, in the above connection design method for the lateral resisting system of the self-centering steel frame, in step 7, the proportion of the bending moment bearing capacity provided by a disc spring in the bending capacity of the whole section is φ_{des} under the action of the large earthquake, and the proportion of the bending moment bearing capacity provided by the C-type energy dissipation steel plate is (1−φ_{des}), so as to calculate the bending moment bearing capacity M_{b} provided by the energy dissipation steel plate to design the section size of the energy dissipation steel plate.

When the inter-storey drift angle reaches 1/50, the disc spring provides the bending moment bearing capacity Mₛ, so the energy dissipation steel plate provides the bending moment bearing capacity:

$${M}_{h} = \frac{( 1 - {φ}_{des} )}{{φ}_{des}} {M}_{S}$$

Mₕ=f_{y}Ad, d is the vertical distance from the axial force direction of the energy dissipation steel plate to the connection rotation point, and the section size of the energy dissipation steel plate can be preliminarily determined.

Preferably, in the above connection design method for the lateral resisting system of the self-centering steel frame, in step 8, according to the column bottom angle θ₂ under the action of the large earthquake, the bending moment Mₚ generated by the prepressure, the bending moment Mₐ generated by the axial force and the bending moment ΔM increased by the deformation of the disc spring group when the column base produces the angle θ₂ can be obtained respectively. The allowable bending moment M_{d} of the column bottom under the action of the large earthquake can be obtained by adding the three. According to the angle θ₁ of the beam column connection under the action of the large earthquake, the bending moment Mₚ′ generated by prepressure when the connection produces angle θ₁, the bending moment M_{b} generated by the C-type energy dissipation steel plate yielding and the bending moment ΔM′ increased by the deformation of the disc spring group can be obtained respectively. The allowable bending moment M_{d}′ of the beam column connection under the action of the large earthquake can be obtained by adding the three.

According to the column bottom angle θ₂ under the action of the large earthquake, the bending moment Mₚ generated by the prepressure, the bending moment Mₐ generated by the axial force and the bending moment ΔM increased by the deformation of the disc spring group when the column base produces the angle θ₂ can be obtained respectively. The allowable bending moment M_{d} of the column bottom under the action of the large earthquake can be obtained by adding the three. According to the angle θ₁ of the beam column connection under the action of the large earthquake, the bending moment Mₚ′ generated by prepressure when the connection produces angle θ₁, the bending moment M_{b} generated by the C-type energy dissipation steel plate yielding and the bending moment ΔM′ increased by the deformation of the disc spring group can be obtained respectively. The allowable bending moment M_{d}′ of the beam column connection under the action of the large earthquake can be obtained by adding the three.

Preferably, in the above connection design method for the lateral resisting system of the self-centering steel frame, in step 9, according to the angular drift of each connection, the axial deformation δ_{y} of the connection disc spring can be obtained, and then the anchor rod axial force generated by the axial deformation of the disc spring can be calculated. By adding the anchor rod axial force with the initial prepressure on the disc spring, the axial force F_{y} and F_{y}′ of each anchor rod of each connection can be obtained.

According to the angular drift of each connection, the axial deformation δ_{y} of the connection disc spring can be calculated, and then the anchor rod axial force generated by the axial deformation of the disc spring can be calculated. The axial force of each anchor rod at each connection can be obtained by adding the initial prepressure on the disc spring.

Preferably, in the above connection design method for the lateral resisting system of the self-centering steel frame, in step 10, the moment of the rotation point of the column base is taken to obtain the column axial force P when the angular drift limit θ₂ is reached, and the local pressure F_{c} of the column flange is obtained through equilibrium conditions; the equivalent beam axial force P′ when the angular drift limit θ₁ is reached is obtained by taking the moment of the rotation point of the beam column connection, and the local pressure F_{c}′ of the beam flange is obtained by the equilibrium conditions.

Preferably, in the above connection design method for the lateral resisting system of the self-centering steel frame, in step 11 and step 12, the design and calculation of the self-centering steel frame connections are completed when the checking results meet the requirements.

Checking steps in step 11 and step 12 are as follows:

1. Column Base Part:

(1) Firstly, Ensuring that the High Strength Anchor Rod May not Yield

$$A \geq {A}_{y} = \frac{{F}_{t 1}}{{σ}_{pt . y}}$$

A—Cross-sectional area of the high strength anchor rod
Fₜ₁—Axial force of the anchor rod at the far end of the rotation point
σ_{pt,y}—Yield stress of the high strength anchor rod

(2) Checking the Strength According to the Strength Checking Formula of Tensile Bending and Compression Bending Members:

$$σ = \frac{P}{A} + \frac{{M}_{d}}{{γ}_{x} \times {ω}_{nx}} \leq f$$

In the formula:
A—Cross-sectional area of the column
γₓ—Plastic development coefficient of section
ωₙₓ—Net sectional modulus with respect to the x-axis

(3) In-Plane Stability Checking:

$$\{ \begin{matrix}{λ}_{x} = \frac{μ {h}_{c}}{{i}_{x}} < [ λ ] \\ \frac{P}{{φ}_{x} A} + \frac{{β}_{mx} {M}_{d}}{{γ}_{x} {ω}_{nx} ( 1 - 0.8 \frac{P}{{N}_{EX}} )} \leq f\end{matrix}$$

Wherein:
l_{c}—Column body height
iₓ—Radius of inertia with respect to the x-axis
φₓ—Stability coefficient of the axial compression member in the acting plane of bending moment, which can be determined by referring to the code
βₘₓ—Equivalent bending moment coefficient
N_{EX}—Parameter,

$${N}_{EX} = \frac{{π}^{2} EA}{1.1 {λ}_{x}^{2}}$$

(4) Local Stability Checking:

Width to thickness ratio of the compression flange of the box section,

$$\frac{{b}_{0}}{t} \leq 40 \sqrt{\frac{235}{{f}_{y}}}$$

(5) Local Pressure at the Column Bottom:

$$σ = \frac{{F}_{C}}{{A}_{fn}} \leq f$$

wherein: A_{fn}—Local pressure sectional area

2. Beam Column Connection Part:

(1) Firstly, Ensuring that the High Strength Pull Rod May not Yield

$$A \geq {A}_{y} = \frac{{F}_{t 1}}{{σ}_{pt . y}}$$

A—Cross-sectional area of the high strength pull rod
Fₜ₁—Axial force of the pull rod at the far end of the rotation point
σ_{pt,y}—Yield stress of the high strength pull rod

(2) Checking the Self-Centering Beam Section

The beam end bending moment shall be less than the plastic bending moment:

M_{d}≤Mₙ=F_{y}Wₓ
F_{y}—Yield stress
Wₓ—Plastic sectional modulus

Checking the strength by a bending strength checking formula:

$$σ = \frac{{P}^{′}}{{A}^{′}} + \frac{{M}_{{d}^{′}}}{{γ}_{x} {w}_{nx}} \leq f$$

A′—Cross-sectional area of the beam
γₓ—Plastic development coefficient of section
ωₙₓ—Net sectional modulus with respect to the x-axis

Local Stability of Compression Flange:

The maximum pressure Fb of the compression flange plate is checked by the following formula (local stability):

$${F}_{b} \leq {F}_{cr} = {k}_{P} \frac{{π}^{2} E}{12 {( 1 - μ )}^{2}} {( \frac{{t}_{w}}{{h}_{0}} )}^{2}$$

kₚ—Elastic buckling coefficient
μ—Poisson ratio
h₀/t_{w}—Height to thickness ratio of compression flange

(3) Shear Check of Beam-Column Joint Surface

The shear strength of the beam-column joint surface is mainly provided by the prepressure provided by the disc spring. The simplified analysis and calculation formula of the shear capacity V of the beam-column joint surface can be obtained as follows:

Vₙ=μ_{f}Fₚᵣ
μ_{f}—Friction coefficient of the beam-column joint surface
Fₚᵣ—Pressure provided by the disc spring at the beam-column joint surface

3. Checking Self-Centering Capability:

If φ_{des} design value is greater than or equal to 0.5, namely Mₚᵣₛ/Mₚ≥0.5 it can ensure that the section meets the requirements of self-centering according to the codes. If φ_{des} design value is less than 0.5, it needs to ensure that the connection meets Mₚᵣₛ≥Mₐₜ+M_{ac} at the zero bound point of opening and closing.
Mₚᵣₛ—Bending moment bearing capacity provided by the disc spring at 1/50 drift angle
Mₐₜ—Bending moment bearing capacity provided by the energy dissipation steel plate at the tension end
M_{ac}—Bending moment bearing capacity provided by the energy dissipation steel plate at the compression end

If checking cannot meet the requirements, φ_{des} needs to be adjusted and the section size of the C-type energy dissipation steel plate is also reduced or the prestress of the disc spring is increased, and the calculation is repeated until the requirements of self-centering are met.

It can be known from the above technical solutions that compared with the prior art, the present invention discloses and provides a connection design method for a lateral resisting system of a self-centering steel frame, and has the following beneficial effects:

1. Strong self-centering ability: the disc spring group of each connection generates restoring force when the structure is deformed, and the restoring force is superimposed with the prepressure of the disc spring group to form the self-centering bending moment, which jointly ensures that the connection and column base have good self-centering performance, so as to realize no damage or slight damage to the connection and the column base under the action of the large earthquake and ensure that the use function of the structure is not interrupted after the earthquake.

2. Strong energy dissipation capacity: existing studies show that the self-centering structure has a larger inter-storey drift angle than the traditional structure under the action of the earthquake. The present invention arranges the energy dissipation devices at the beam column connections to give full play to the energy dissipation characteristics of metal plastic deformation.

3. The structural components are independent in functions, clear in force and definite in force transmission: the vertical load of the main structure is mainly borne by the prepressure provided by the disc spring; different from the traditional energy-dissipating angle steel which bears both shear resistant and energy dissipation purposes, the C-type energy dissipation steel plates are easy to deform under the stress and do not increase the bearing capacity and shearing resistance, which is convenient for the calculation of the stress of the main structure.

4. According to the design method for the self-centering structure provided by the present invention, the present invention conducts the checking of the bearing capacity and the stability under the action of large earthquakes on the basis of meeting the requirements of small earthquakes. The calculation methods are simple and feasible, can ensure more accurate results, and have good popularization and application values.

### DESCRIPTION OF DRAWINGS

To more clearly describe the technical solution in the embodiments of the present invention or in the prior art, the drawings required to be used in the description of the embodiments or the prior art will be simply presented below. Apparently, the drawings in the following description are merely the embodiments of the present invention, and for those ordinary skilled in the art, other drawings can also be obtained according to the provided drawings without contributing creative labor.

FIG. 1 is a flow chart of a connection design method for a lateral resisting system of a self-centering steel frame provided by the present invention;

FIG. 2 is a schematic diagram of an integral structure provided by the present invention;

FIG. 3 is a structural schematic diagram of self-centering column base connections provided by the present invention;

FIG. 4 is a structural schematic diagram of self-centering column base connections provided by the present invention;

FIG. 5 is a top view of a self-centering column base provided by the present invention;

FIG. 6 is a calculation diagram of column base connections provided by the present invention;

FIG. 7 is a calculation diagram of beam column connections under the action of a small earthquake provided by the present invention;

FIG. 8 is a calculation diagram of a subframe in calculation of rotational stiffness at both ends provided by the present invention;

FIG. 9 is a calculation diagram of a column component in calculation of drift of column end by a force method or a drift method provided by the present invention;

FIG. 10 is a force analysis diagram of a column base when θ2 drift is generated at a column bottom provided by the present invention;

FIG. 11 is a force analysis diagram of beam column connections when θ1 drift is generated at a column top provided by the present invention.

Wherein:
1—foundation;
11—limiting groove; 12—cushioning rubber pad;
2—steel column;
21—bottom plate; 22—supporting plate;
3—cross beam;
4—self-centering column base structure;
41—embedded steel plate; 42—suspension board; 43—anchor rod; 44—first disc spring group; 45—first high strength nut; 46—flange reinforcing plate;
5—self-centering connection structure;
51—end plate; 52—high strength pull rod; 53—C-type energy dissipation steel plate; 54—second high strength nut; 55—second disc spring group; 56—stiffening rib.

### DETAILED DESCRIPTION

The technical solution in the embodiments of the present invention will be clearly and fully described below in combination with the drawings in the embodiments of the present invention. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

### Embodiment 1

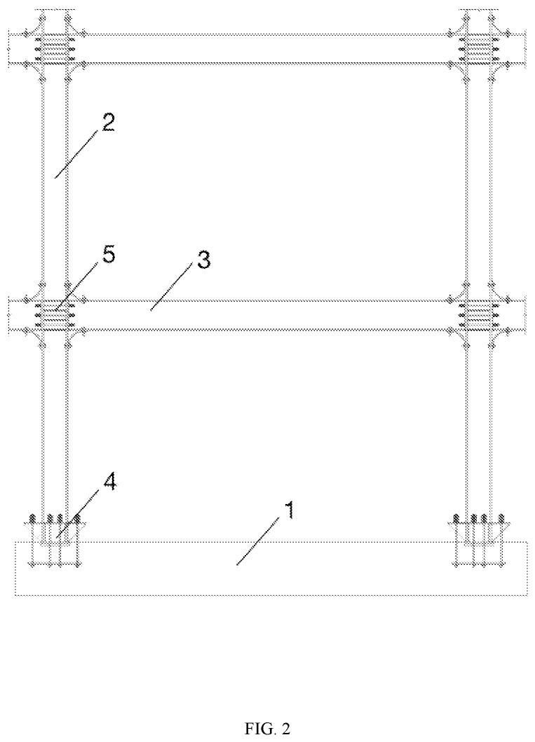

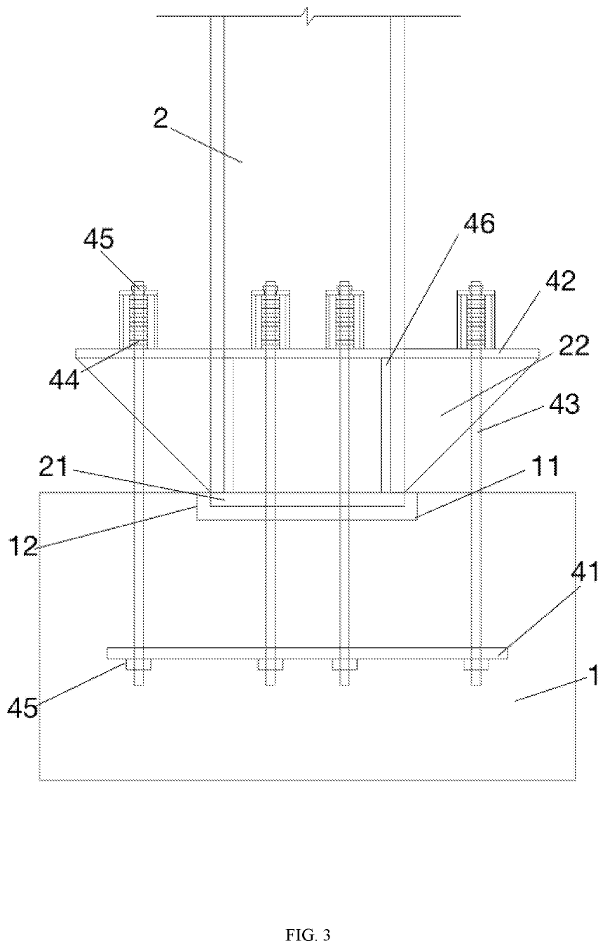

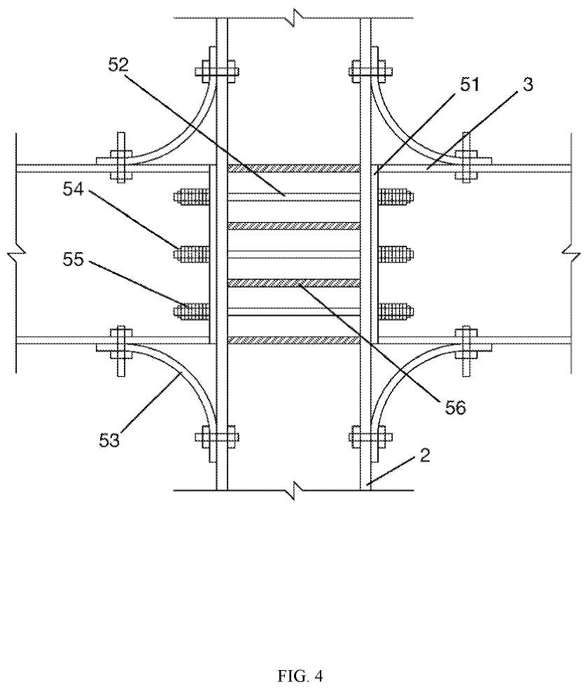

By referring to FIG. 2 to FIG. 5, a lateral resisting system of a self-centering steel frame comprises: a foundation 1, steel columns 2 and cross beams 3;

The steel columns 2 are I-steel or square steel tubes or concrete filled steel tubes. When the steel columns 2 are I-steel, in a self-centering column base structure 4, the inner sides of flanges of the steel columns 2 are fixed with flange reinforcing plates 46. The steel columns 2 are vertically arranged on the top surface of the foundation 1, and the bottom ends of the steel columns 2 are connected with the foundation 1 to form a self-centering column base structure 4. The cross beams 3 are horizontally arranged, and ends are connected with the side walls of the steel columns 2; and the steel columns 2 and the cross beams 3 connected at both sides form a self-centering connection structure 5.

The self-centering column base structure 4 comprises an embedded steel plate 41, a suspension board 42, anchor bolts 43 and a first disc spring group 44. The embedded steel plate 41 is embedded inside the foundation 1. The suspension board 42 is horizontally fixed to the surrounding side wall of the steel column 2 near the foundation 1. Eight anchor rods 43 are arranged, and are vertically distributed; both ends of the anchor rods 43 pass through the suspension board 42 and the embedded steel plate 41 respectively, and are fastened through first high strength nuts 45. The first disc spring group 44 is sleeved at the top ends of the anchor rods 43, and abutted between the top surface of the suspension board 42 and the first high strength nuts 45 at the top end. Rigid backup plates are cushioned above and below the first disc spring group 44. The top surface of the foundation 1 is provided with a limiting groove 11 through which the steel columns 2 are inserted; a bottom plate 21 is fixed at the bottom ends of the steel columns 2; and a cushioning rubber pad 12 is fixed between the bottom plate 21 and the limiting groove 11. A supporting plate 22 is fixed between the bottom surface of the suspension board 42 and the side wall of the steel column 2.

The self-centering connection structure 5 comprises end plates 51, high strength pull rods 52 and C-type energy dissipation steel plates 53; the end plates 51 are fixed to the ends of the cross beams 3; and three high strength pull rods 52 are arranged, horizontally penetrate through the side walls of the steel columns 2 and the two end plates 51, and are fastened at both ends through second high strength nuts 54. At least one end of the high strength pull rods 52 is sleeved with a second disc spring group 55 abutted between the end plates 51 and the second high strength nuts 54; four C-type energy dissipation steel plates 53 are arranged; and both ends of the C-type energy dissipation steel plates 53 are fixedly connected with the side walls of the steel columns 2 and flanges of the cross beams 3 respectively. A plurality of stiffening ribs 56 are welded and fixed between two side walls of the steel columns 2, and the stiffening ribs 56 are arranged up and down between the high strength pull rods 52; the highest layout horizontal plane of the plurality of stiffening ribs 56 is flush with the top surface of the cross beams 3, and the lowest layout horizontal plane is flush with the bottom surface of the cross beams 3. Both ends of the C-type energy dissipation steel plates 53 are welded and fixed with the side walls of the steel columns 2 and the flanges of the cross beams 3, or fixed with bolts respectively.

The principle of the lateral resisting system of the steel frame in the present embodiment is: when an earthquake comes, firstly, the C-type energy dissipation steel plates 53 located at the beam column connections dissipate the seismic energy; then, the deformation of the second disc spring group 55 on the beam column connection is increased, and the anchor rods 43, the first disc spring group 44 and the suspension board 42 at the lower parts of the steel columns 2 jointly form the self-centering column base; and the prepressing bending moment is formed through the prepressure of the disc spring group, to jointly ensure that the connections and the column base have good self-centering performance and finally realize the lateral resistance, energy dissipation and self-centering functions of the whole system. The lateral resisting system has the characteristics of strong lateral resistance, self-centering and energy dissipation capability, is clear in concept, convenient in construction and reasonable in building cost, and will be widely used in high-rise and super high-rise building structures.

The present invention has the characteristics of strong lateral resistance, self-centering and energy dissipation capability. The present invention is clear in concept, convenient in construction and reasonable in building cost, and will be widely used in high-rise and super high-rise building structures.

### Embodiment 2

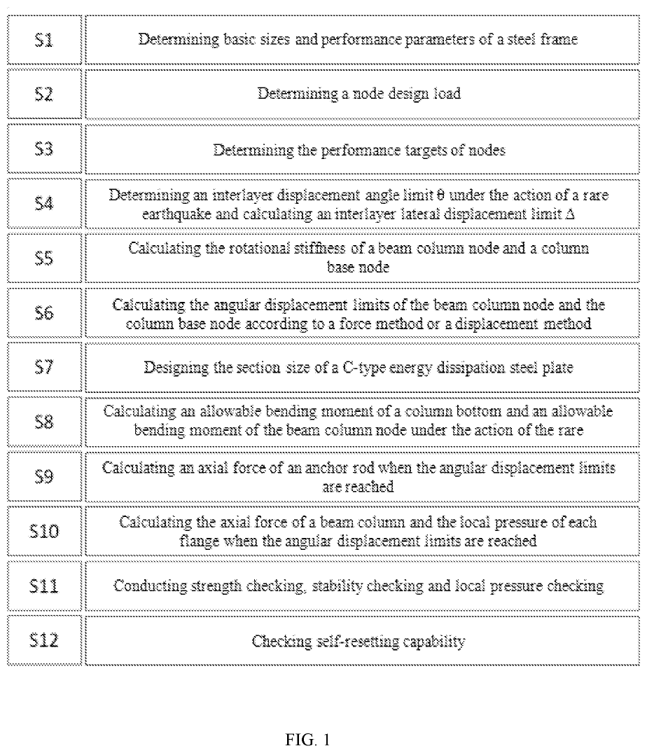

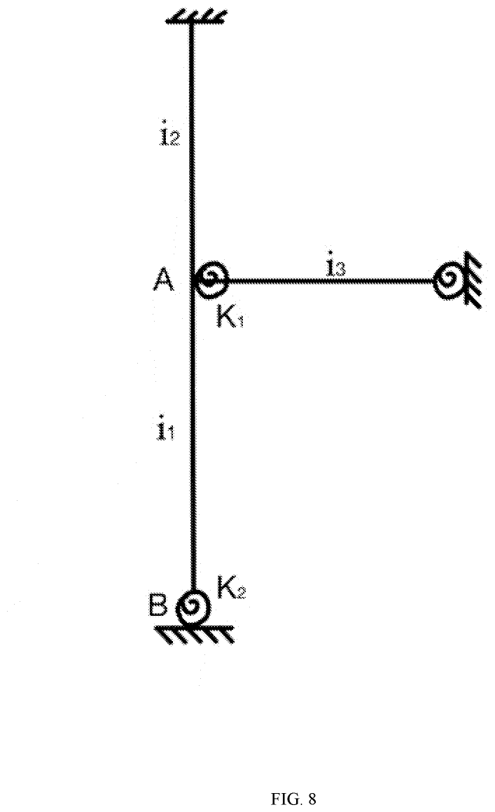

By referring to FIG. 1 and FIG. 6 to FIG. 11, embodiments of the present invention disclose a connection design method for a lateral resisting system of a self-centering steel frame, with an example of isolating a subframe, as shown in FIG. 8, comprising the following steps:

S1: determining basic dimension parameters of components of a steel frame, comprising:

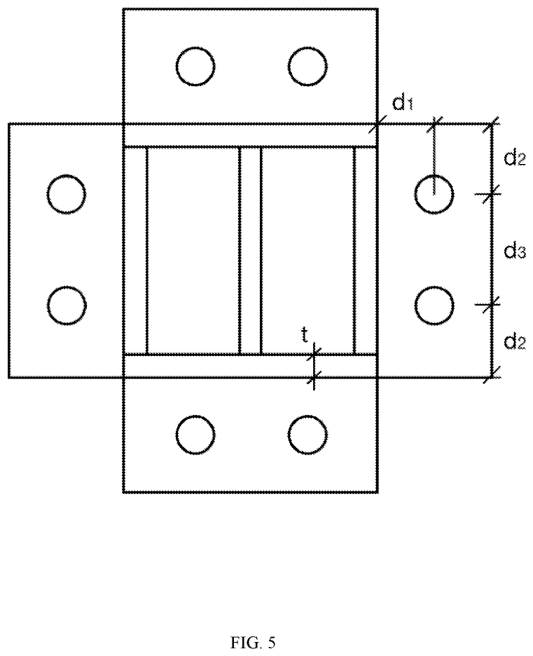

the section sizes and heights of steel columns and steel beams, and the basic parameters of the used steel comprise sectional inertia moment I and elastic modulus E; by referring to FIG. 5, the section sizes of the bottom are as follows:
b, h, t, d₁, d₂ and d₃;

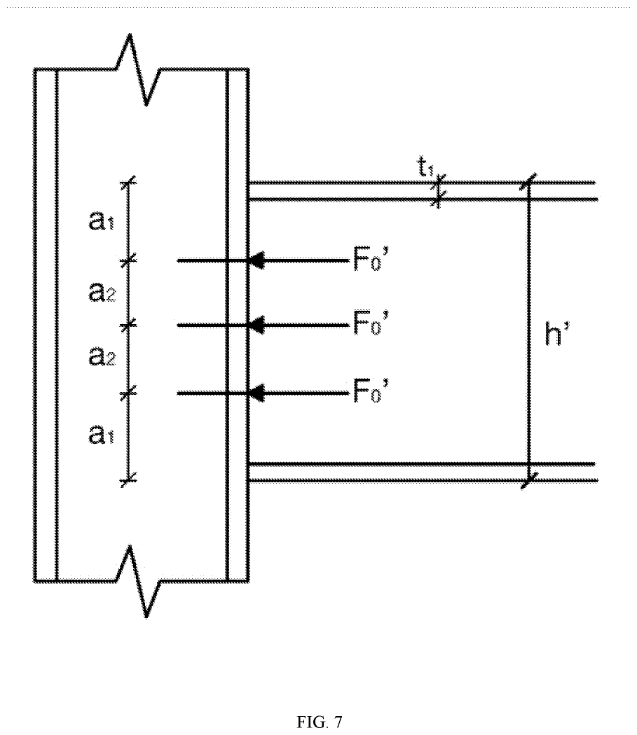

By referring to FIG. 7, the sizes of the beam column connections are as follows:
a₁,a₂,t₁;

The column steel is selected from Q345 steel, the column height is h_{c}, the beam section height is h′, and the beam length is L; and the elastic modulus E is known according to the properties of materials, and the sectional inertia moment I can be obtained through calculation.

S2: determining a connection design load, wherein the shearing force of the column bottom is resisted by embedding shear keys in the foundation, and the shear keys only constrain the horizontal lateral movement of the column base.

After consideration, the elastic effect of the structure is calculated under the action of small earthquakes, and then the design internal force required by each connection is obtained through the combination of load effects. The maximum bending moment of the column bottom of the steel column under the action of a small earthquake is M, the maximum bending moment of the beam end at the beam column connections is Mₜ, and column axial force is N;

S3: determining the performance targets of connections when designing self-centering connections; determining the prepressure F₀ to be applied for each anchor rod at the column bottom according to the performance-based design requirements in the current seismic codes so that the flanges of the column base are not separated from the foundation, and prepressure F₀′ to be applied for the beam column connection so that beam flanges are not separated from the side walls of the columns.

The bending moment M at the column bottom under the action of small earthquakes is known from the above calculation of the internal force. In order to prevent the column base from lifting, the bending moment value generated by the prepressure and the axial force on the rotation point of the column base shall be greater than the bending moment M at the column bottom under the action of small earthquakes, namely:

N×0.5 h+M₀≥M;

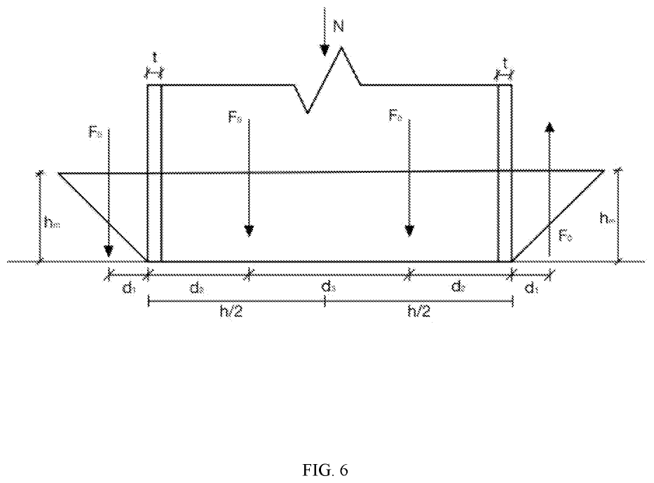

The bending moment M at the column bottom under the action of small earthquakes is known. In order to prevent the column base from lifting, the bending moment value generated by the prepressure and the axial force on the column edge shall be greater than the bending moment M at the column bottom under the action of small earthquakes. A calculation diagram is shown in FIG. 6, namely:

$$[ \frac{1}{2} N ( h - t ) + 2 {F}_{0} ( {d}_{1} + h - \frac{1}{2} t ) + 2 {F}_{0} ( {d}_{2} + {d}_{3} - \frac{1}{2} t ) + 2 {F}_{0} ( {d}_{2} - \frac{1}{2} t ) + 2 {F}_{0} ( {d}_{1} + \frac{1}{2} t ) ] \geq M$$

Wherein: t is the thickness of the sectional steel plate, h is the sectional height of the column, and d₁, d₂, d₃ and axial force are known, so the minimum prepressure F₀ of each anchor rod can be calculated.

According to F₀, the number of disc springs required by the first disc spring group and the combination form are determined, and the axial stiffness K_{S} of the disc spring group is determined.

The bending moment Mₜ at the beam column connection under the action of small earthquakes is known. In order to keep the beam column connection closed, the bending moment value generated by the prepressure on the flanges of the beams shall be greater than the bending moment Mₜ at the column top under the action of small earthquakes. A calculation diagram is shown in FIG. 7, namely:

$${F}_{0}^{′} ( {a}_{1} + 2 {a}_{2} - \frac{1}{2} {t}_{1} ) + {F}_{0}^{′} ( {a}_{1} + {a}_{2} - \frac{1}{2} {t}_{1} ) + {F}_{0}^{′} ( {a}_{1} - \frac{1}{2} {t}_{1} ) \geq {M}_{t}$$

In the formula: t₁ is the thickness of the beam flange plate, and a₁ and a₂ are known, so the minimum prepressure F₀′ of each anchor rod can be calculated.

According to F₀′, the number of disc springs required by the second disc spring group and the combination form are determined, and the axial stiffness K_{S}′ of the disc spring group is determined.

S4: determining an inter-storey drift angle limit θ in a large earthquake according to the current building seismic design code of China, and then calculating an inter-storey lateral drift limit Δ;

When the angle is very small, tanx=x, so Δ/h_{c}=0; h_{c} is the column height, and h_{c} and θ are both known, so the following can be obtained:

inter-storey lateral drift limit Δ=h_{c}×θ;

S5: calculating the rotational stiffness K₁ and K₂ of the column top and the column bottom;

A calculation diagram is shown in FIG. 8;

B-end rotational stiffness caused by the disc spring group:

$${K}_{2}^{′} = 2 {k}_{s} [ {( {d}_{1} + h - \frac{1}{2} t )}^{2} + {( {d}_{2} + {d}_{3} - \frac{1}{2} t )}^{2} + {( {d}_{2} - \frac{1}{2} t )}^{2} + {( {d}_{1} + \frac{1}{2} t )}^{2} ]$$

Column line stiffness i₁=EI/h_{c}

Upper column line stiffness is i₂ and beam line stiffness is i₃;

A-end rotational stiffness caused by the disc spring group:

K₁′=kₛ′[a₁²+(a₁+a₂)²+(a₁+2a₂)²]

A-end rotational stiffness caused by adjacent beams and columns: K₁″=3.5i₂;

$$α = \frac{28 \times ( {i}_{1} + {i}_{2} ) - 4 \times {i}_{1}}{7 \times ( {i}_{1} + {i}_{2} ) + {i}_{1}}$$

Point A provides rotational stiffness for point B: K₂″=αi₁;

The lateral stiffness of rotating constraint rods at both ends is calculated as follows:

The rotational stiffnesses at both ends are K₁ and K₂, rod length is 1 and line stiffness is i;

$${D}_{j} = \frac{12 i}{{l}^{2}} ( \frac{{K}_{1} {K}_{2} + i ( {K}_{1} + {K}_{2} )}{{K}_{1} {K}_{2} + 4 i ( {K}_{1} + {K}_{2} ) + 12 {i}^{2}} )$$

The lateral stiffness at the column top is D=ΣDⱼ

The rotational stiffness transmitted by K₂′ to the column top iₛ K1″′:

$${K}_{1}^{′′′} = 4 i ( \frac{D \times {K}_{2}^{′} \times {h}_{c}^{2} + 3 i \times {K}_{2}^{′} + 3 i \times D \times {h}_{c}^{2}}{D \times {K}_{2}^{′} \times {h}_{2 c}^{2} + 4 i \times D \times {h}_{c}^{2} + 12 {i}^{2} + 3 i \times {K}_{2}^{′}} )$$

The rotational stiffness transmitted by K₁′ to the column bottom iₛ K₂″′:

$${K}_{2}^{′′′} = 4 i ( \frac{{K}_{1}^{′} + 3 i}{{K}_{1}^{′} + 4 i} )$$

To sum up:

K₁=K₁′+K₁″+K₁″′

K₂=K₂′+K₂″+K₂′″

S6: calculating the angular drift limits θ₁ and θ₂ of the column top and the column bottom in a large earthquake according to a force method or a drift method;

The rotational stiffness K₁ and K₂ at both ends of the column, the horizontal lateral movement A at the column top and the column body line stiffness i₁ are known;

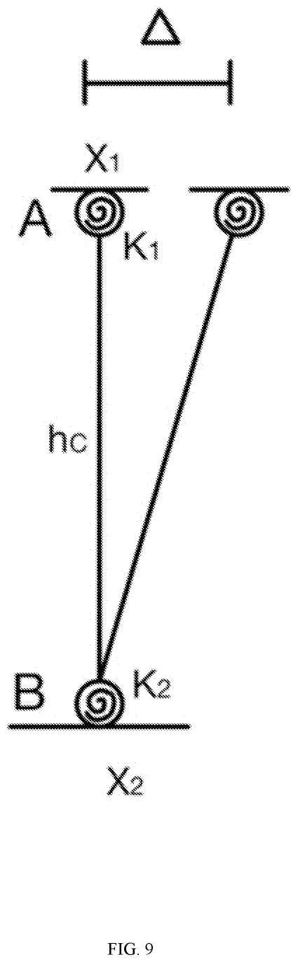

A calculation diagram is shown in FIG. 9, and equations of the force method are listed as follows:

$$\{ \begin{matrix}{δ}_{11} {X}_{1} + {δ}_{12} {X}_{2} - \frac{Δ}{{h}_{c}} = - \frac{{X}_{1}}{{K}_{1}} \\ {δ}_{21} {X}_{1} + {δ}_{22} {X}_{2} - \frac{Δ}{{h}_{c}} = - \frac{{X}_{2}}{{K}_{2}}\end{matrix}$$

X₁ and X₂ are bending moments at the column end, and the direction is counterclockwise.

Wherein δ₁₁=δ₂₂=1/(3i), and δ₁₂=δ₂₁=−1/(6i);

The simultaneous equations are solved to obtain the bending moment value X₁ at the column top and the bending moment value X₂ at the column bottom;

θ₁−X₁/K₁,θ₂=X₂/K₂

A drift method is also used for checking results:

$$\{ \begin{matrix}4 i {θ}_{1} + 2 i {θ}_{2} + \frac{6 i}{{h}_{c}} Δ = - {k}_{1} {θ}_{1} \\ 4 i {θ}_{2} + 2 i {θ}_{1} + \frac{6 i}{{h}_{c}} Δ = - {k}_{2} {θ}_{2}\end{matrix}$$

The results are consistent, and the angular drift limits θ₁ and θ₂ of the column top and the column bottom in the large earthquake are obtained.

S7: The proportion of the bending moment bearing capacity provided by a disc spring in the bending capacity of the whole section is φ_{des} under the action of the large earthquake, and the proportion of the bending moment bearing capacity provided by the C-type energy dissipation steel plate is (1−φ_{des}), so as to calculate the bending moment bearing capacity M_{b} provided by the energy dissipation steel plate to design the section size of the energy dissipation steel plate.

When the inter-storey drift angle reaches 1/50, the disc spring provides the bending moment bearing capacity Mₛ, and the energy dissipation steel plate provides the bending moment bearing capacity Mₕ:

$${M}_{h} = \frac{( 1 - {φ}_{des} )}{{φ}_{des}} {M}_{S} , and {M}_{h} = {f}_{y} Ad$$

d is the vertical distance from the axial force direction of the energy dissipation steel plate to the connection rotation point, and the section size of the energy dissipation steel plate can be preliminarily determined.

φ_{des}=0.6. When the inter-storey drift angle reaches 1/50, the compression drift of the disc spring is L=θh. h is the vertical distance between the axial force exerted by the disc spring group and the rotation center of the connection. Therefore, the axial force F_{y}=F₀+K_{S}L after compression of the disc spring group can be calculated. The moment of the axial force of each disc spring group for the rotation center can be obtained as follows:

$${M}_{s} = {θ}_{1} {K}_{S} ( 3 {a}_{1}^{2} + 5 {a}_{2}^{2} + 6 {a}_{1} {a}_{2} ) \\ {M}_{h} = \frac{( 1 - {φ}_{des} )}{{φ}_{des}} {M}_{S} , {M}_{h} = {f}_{y} Ad ,$$

The sectional area A of the energy dissipation steel plate can be calculated. The thickness of the energy dissipation steel plate should not exceed the thickness of the beam flange, and the width should be consistent with the beam flange.

S8: determining the allowable bending moment M_{d} of the column bottom and the allowable bending moment M_{d} of the beam column connection under the large earthquake according to a column axial force, an inter-storey horizontal force, anchor rod prepressure, disc spring deformation force and the angular drift limits.

According to the column bottom angle θ₂ under the action of the large earthquake, the bending moment Mₚ generated by the prepressure, the bending moment Mₐ generated by the axial force and the bending moment ΔM increased by the deformation of the disc spring group when the column bottom produces the angle θ₂ can be obtained respectively. The allowable bending moment M_{d} of the column bottom under the action of the large earthquake can be obtained by adding the three.

$${M}_{p} = 2 {F}_{0} ( {d}_{1} + h - \frac{1}{2} t - {h}_{m} sin {θ}_{2} ) + 2 {F}_{0} ( {d}_{2} + {d}_{3} - \frac{1}{2} t - {h}_{m} sin {θ}_{2} ) + 2 {F}_{0} ( {d}_{2} - \frac{1}{2} t - {h}_{m} sin {θ}_{2} ) + 2 {F}_{0} ( {d}_{1} + \frac{1}{2} t - {h}_{m} sin {θ}_{2} )$$

$${M}_{a} = N ( \frac{h}{2} - {h}_{c} sin {θ}_{2} )$$

$$Δ M = 2 {K}_{s} {θ}_{2} [ {( {d}_{1} + h - \frac{1}{2} t - {h}_{m} sin {θ}_{2} )}^{2} + {( {d}_{2} + {d}_{3} - \frac{1}{2} t - {h}_{m} sin {θ}_{2} )}^{2} + {( {d}_{2} - \frac{1}{2} t - {h}_{m} sin {θ}_{2} )}^{2} + {( {d}_{1} + \frac{1}{2} t - {h}_{m} sin {θ}_{2} )}^{2} ]$$

hₘ is the vertical distance between the suspension board and the ground, as shown in FIG. 6;

M_{d}=Mₚ+Mₐ+ΔM;

According to the angle θ₁ of the column top under the action of the large earthquake, the bending moment Mₚ′ generated by prepressure when the column top produces angle θ₁, the bending moment M_{b} generated by the energy dissipation steel plate yielding and the bending moment ΔM′ increased by the deformation of the disc spring group can be obtained respectively. The allowable bending moment M_{d}′ of the column top under the action of the large earthquake can be obtained by adding the three.

$${M}_{p}^{′} = {F}_{0}^{′} ( {a}_{1} + 2 {a}_{2} - \frac{1}{2} {t}_{1} ) \frac{sin {θ}_{1}}{{θ}_{1}} + {F}_{0}^{′} ( {a}_{1} + {a}_{2} - \frac{1}{2} {t}_{1} ) \frac{sin {θ}_{1}}{{θ}_{1}} + {F}_{0}^{′} ( {a}_{1} - \frac{1}{2} {t}_{1} ) \frac{sin {θ}_{1}}{{θ}_{1}}$$

$$Δ {M}^{′} = {K}_{s} {θ}_{1} [ {( {a}_{1} + 2 {a}_{2} - \frac{1}{2} {t}_{1} )}^{2} + {( {a}_{1} + {a}_{2} - \frac{1}{2} {t}_{1} )}^{2} + {( {a}_{1} - \frac{1}{2} {t}_{1} )}^{2} ] \\ {M}_{b} = {f}_{y} {Ad}^{′}$$

In the formula, f_{y} is the yield strength of the energy dissipation steel plate, A is the sectional area of the energy dissipation segment, and d′ is the vertical distance from the center of the energy dissipation section to the rotation point.

M_{d}′=Mₚ′+ΔM′+M_{b}

S9: calculating the axial forces F_{y} and F_{y}′ of the anchor rods when the angular drift limits are reached according to the angular drift limits of the column bottom and the column top;

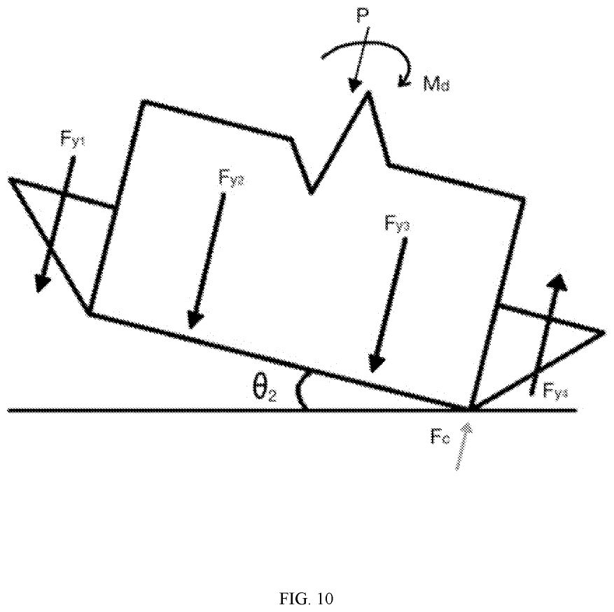

According to the angular drift of the column bottom, the axial deformation δ_{y} of the disc spring in the first disc spring group can be calculated, and then the axial force generated by the axial deformation of the disc spring can be calculated. The axial force F_{y} of each pull rod can be obtained by adding the axial force with the prepressure applied initially by the disc spring. Force analysis is shown in FIG. 10.

$${F}_{y 1} = {δ}_{y 1} {K}_{S} + {F}_{0} = {θ}_{2} ( {d}_{1} + h - \frac{1}{2} t ) {K}_{S} + {F}_{0} \\ {F}_{y 2} = {δ}_{y 2} {K}_{S} + {F}_{0} = {θ}_{2} ( {d}_{1} + {d}_{3} - \frac{1}{2} t ) {K}_{S} + {F}_{0} \\ {F}_{y 3} = {δ}_{y 3} {K}_{S} + {F}_{0} = {θ}_{2} ( {d}_{2} - \frac{1}{2} t ) {K}_{S} + {F}_{0} \\ {F}_{y 4} = {δ}_{y 4} {K}_{S} + {F}_{0} = {θ}_{2} ( {d}_{1} + \frac{1}{2} t ) {K}_{S} + {F}_{0}$$

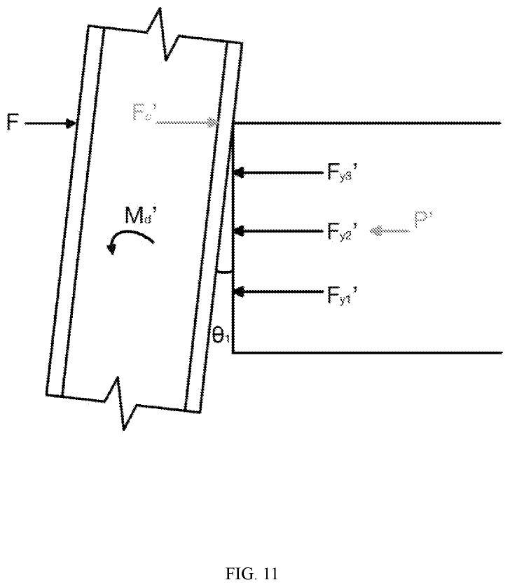

According to the angular drift of the column top, the axial deformation δ_{y}′ of the disc spring in the second disc spring group can be calculated, and then the axial force generated by the axial deformation of the disc spring can be calculated. The axial force F_{y}′ of each anchor rod can be obtained by adding the axial force with the prepressure applied initially by the disc spring. Force analysis is shown in FIG. 11.

$${F}_{y 1}^{′} = {δ}_{y 1}^{′} {K}_{S} + {F}_{0}^{′} = {θ}_{2} ( {a}_{1} + 2 {a}_{2} - \frac{1}{2} {t}_{1} ) {K}_{S} + {F}_{0}^{′} \\ {F}_{y 2}^{′} = {δ}_{y 2}^{′} {K}_{S} + {F}_{0}^{′} = {θ}_{2} ( {a}_{1} + {a}_{2} - \frac{1}{2} {t}_{1} ) {K}_{S} + {F}_{0}^{′} \\ {F}_{y 3}^{′} = {δ}_{y 3}^{′} {K}_{S} + {F}_{0}^{′} = {θ}_{2} ( {a}_{1} - \frac{1}{2} {t}_{1} ) {K}_{S} + {F}_{0}^{′}$$

S10: taking the moment of a rotation point to obtain the axial force of the beam column when the angular drift limits are reached, and the local pressure of each connection flange is obtained through equilibrium conditions.

The rotation point of the column bottom:

$${M}_{d} = 2 {F}_{y 1} ( {d}_{1} + h - \frac{1}{2} t ) + 2 {{F}_{y 2} ( {d}_{2} + {d}_{3} - \frac{1}{2} t )}_{+ 2} {{F}_{y 3} ( {d}_{2} - \frac{1}{2} t )}_{+ 2} {F}_{y 4} ( {d}_{1} + \frac{1}{2} t ) + P ( h - t ) / 2 ;$$

The axial pressure P of the column body when the angular drift reaches θ₂ under the action of the large earthquake is calculated.

So, F_{c}=F_{y1}+F_{y2}+F_{y3}+P−F_{y4}

The rotation point of the beam column:

The lateral drift stiffness of the frame is known. According to the inter-storey horizontal drift, the inter-storey horizontal force can be calculated; the equivalent beam axial force P′ when the angular drift limit θ₁ is reached is obtained by taking the moment of the rotation point of the beam column, and the local pressure F,′ of the beam flange is obtained by the equilibrium conditions, as shown in FIG. 10 and FIG. 11.

$$F = Δ \times D ;$$

$${M}_{d}^{′} = {F}_{y 1}^{′} ( {a}_{1} + 2 {a}_{2} - \frac{1}{2} {t}_{1} ) + {F}_{y 2}^{′} ( {a}_{1} + {a}_{2} - \frac{1}{2} {t}_{i ) +} {F}_{y 3}^{′} ( {a}_{1} - \frac{1}{2} {t}_{1} ) + {P}^{′} ( {h}^{′} - {t}_{1} ) / 2 ;$$

The equivalent beam axial force P′ when the angular drift reaches θ₁ is obtained under the action of the large earthquake.

So, F_{c}′=F_{y1}′+F_{y2}′+F_{y3}′+F+P′

S11: conducting strength checking, stability checking and local pressure checking.

1. Column Base Connection Part:

(1) Ensuring that the High Strength Anchor Rod May not Yield:

The anchor rod at the farthest end from the rotation point is checked, and the axial force of the anchor rod is

$${F}_{t 1} = {θ}_{2} ( {d}_{1} + h - \frac{1}{2} t ) {K}_{S} + {F}_{0}$$

The yield stress of the anchor rod is σ_{pt,y}, and the minimum cross-sectional area of the high strength anchor rod is

$${A}_{y} = \frac{{F}_{t 1}}{{σ}_{pt \cdot y}} .$$

When the cross-sectional area of the high strength anchor rod meets A≥A_{y}, the requirement is satisfied.

(2) Checking the Strength According to the Strength Checking Formula of Tensile Bending and Compression Bending Members:

The cross-sectional area A of the column is known.

The plastic development coefficient γₓ of the section and the net sectional modulus ωₙₓ with respect to the x-axis can be obtained by table look-up or calculation. P is known, so σ can be calculated.

When

$$σ = \frac{P}{A} + \frac{{M}_{d}}{{γ}_{x} \times {ω}_{nx}} \leq f ,$$

the strength checking of the column base meets the requirement.

(3) In-Plane Stability Checking:

Because the bottom of the column base rotates and separates from a foundation beam, both ends of the column are assumed to be hinged. Then, μ=1.0

$${i}_{x} = \sqrt{\frac{I}{A}} , when {λ}_{x} = \frac{μ {h}_{c}}{{i}_{x}} < [ λ ] ,$$

the requirement is satisfied, wherein [λ]=150.

For b type section, coefficient

$${λ}_{x} \sqrt{\frac{{f}_{y}}{235}}$$

is calculated, and ωₓ can be obtained by referring to the code.

The reverse curvature is generated by the end bending moment and the lateral load,

$${β}_{mx} = 0.85 , {N}_{EX} = \frac{{π}^{2} EA}{1.1 {λ}_{x}^{2}}$$

When

$$\frac{P}{{φ}_{x} A} + \frac{{β}_{mx} {M}_{d}}{{γ}_{x} {ω}_{nx} ( 1 - 0.8 \frac{P}{{N}_{EX}} )} < f ,$$

the requirement is satisfied.

(4) Local Stability Checking:

When

$$\frac{{b}_{0}}{t} \leq 40 \sqrt{\frac{235}{{f}_{y}}} ,$$

the requirement is satisfied.

(5) Local Pressure at the Column Bottom:

When

$$σ = \frac{{F}_{C}}{{A}_{fn}} \leq f ,$$

the requirement is satisfied, wherein A_{fn}=th is the local contact area.

2. Beam Column Connection Part:

(1) Firstly, Ensuring that the High Strength Pull Rod May not Yield:

The pull rod at the farthest end from the rotation point is checked, and the axial force of the pull rod is

$${F}_{t 1} = {θ}_{1} ( {a}_{1} + 2 {a}_{2} - \frac{1}{2} {t}_{1} ) {K}_{S} + {F}_{0}^{′}$$

The yield stress of the pull rod is σ_{pt,y}, and the minimum cross-sectional area of the high strength pull rod is

$${A}_{y} = \frac{{F}_{t 1}}{{σ}_{pt \cdot y} .}$$

When the cross-sectional area of the high strength pull rod meets A≥A_{y}, the requirement is satisfied.

(2) Checking the Self-Centering Beam Section:

Plastic moment is Mₙ=F_{y}Wₓ, F_{y} is yield stress and Wₓ is plastic sectional modulus. The beam end bending moment M_{d}′ can be calculated:

When

$${M}_{d}^{′} = {F}_{y 1}^{′} ( {a}_{1} + 2 {a}_{2} - \frac{1}{2} {t}_{1} ) + {F}_{y 2}^{′} ( {a}_{1} + {a}_{2} - \frac{1}{2} {t}_{i ) +} {F}_{y 3}^{′} ( {a}_{1} - \frac{1}{2} {t}_{1} ) + {P}^{′} ( {h}^{′} - {t}_{1} ) / 2$$

and M_{d}′≤Mₙ, the requirement is satisfied.

(3) Checking the Strength According to the Strength Checking Formula of Tensile Bending and Compression Bending Members:

Because the beam section parameter is known, the beam sectional area A′ can be calculated. The net sectional modulus ωₙₓ with respect to the x-axis and the plastic development coefficient γₓ of the section can be obtained by table look-up.

$$σ = \frac{P ′}{A ′} + \frac{{M}_{{d}^{′}}}{{γ}_{x} {ω}_{nx}} \leq f ,$$

When the requirement is satisfied.

(4) Checking Local Stability of the Compression Flange:

Critical elastic buckling force of the compression flange of the compression bending member is

$${F}_{cr} = {k}_{P} \frac{{π}^{2} E}{12 {( 1 - μ )}^{2}} {( \frac{{t}_{w}}{{h}_{0}} )}^{2} .$$

In the formula: kₚ is the elastic buckling coefficient, μ is the poison ratio, h₀/t_{w} is the height to thickness ratio of the compression flange, and F_{cr} is the critical elastic buckling force of the compression flange. When the maximum pressure of the compression flange plate is F_{b}≤F_{cr}, the requirement is satisfied.

3. Checking Self-Centering:

If φ_{des} design value is greater than or equal to 0.5, namely Mₚᵣₛ/Mₚ≥0.5, it can ensure that the section meets the requirements of self-centering according to the codes. If φ_{des} design value is less than 0.5, it needs to ensure that the connection meets Mₚᵣₛ≥Mₐₜ+M_{ac} at the zero bound point of opening and closing.
Mₚᵣₛ—Bending moment bearing capacity provided by the disc spring at 1/50 drift angle;
Mₐₜ—Bending moment bearing capacity provided by the energy dissipation steel plate at the tension end;
M_{ac}—Bending moment bearing capacity provided by the energy dissipation steel plate at the compression end;

When all the above checking results meet the requirements, the connection design for the lateral resisting system of the self-centering steel frame is completed. If the requirements cannot be met, φ_{des} needs to be adjusted and the section of the C-type energy dissipation steel plate is also reduced or the prestress of the disc spring is increased, and the calculation is repeated until the requirements of self-centering are met.

According to the connection design method for the lateral resisting system of the self-centering steel frame provided by the present invention, the method conducts the checking of the bearing capacity and the stability under the action of large earthquakes on the basis of meeting the requirements of small earthquakes. The calculation methods are simple and feasible, can ensure more accurate results, and have good popularization and application values. The lateral resisting system of the steel frame designed by the method has the characteristics of strong lateral resistance, self-centering and energy dissipation capability. The present invention is clear in concept, convenient in construction and reasonable in building cost, and will be widely used in high-rise and super high-rise building structures. The vertical load of the main structure is mainly borne by the prepressure provided by the disc spring; different from the traditional energy-dissipating angle steel which bears both shear resistant and energy dissipation purposes, the C-type energy dissipation steel plates are easy to deform under the stress and do not increase the bearing capacity and shearing resistance, which is convenient for the calculation of the stress of the main structure.

Each embodiment in the description is described in a progressive way. The difference of each embodiment from each other is the focus of explanation. The same and similar parts among all of the embodiments can be referred to each other. For a device disclosed by the embodiments, because the device corresponds to a method disclosed by the embodiments, the device is simply described. Refer to the description of the method part for the related part.

The above description of the disclosed embodiments enables those skilled in the art to realize or use the present invention. Many modifications to these embodiments will be apparent to those skilled in the art. The general principle defined herein can be realized in other embodiments without departing from the spirit or scope of the present invention. Therefore, the present invention will not be limited to these embodiments shown herein, but will conform to the widest scope consistent with the principle and novel features disclosed herein.

What is claimed is:

1. A connection design method for a lateral resisting system of a self-centering steel frame, comprising the following steps:
step 1: determining dimension parameters and material characteristics of components of a steel frame;
step 2: determining a connection design load;
step 3: determining the performance targets of connections;
step 4: determining an inter-storey drift angle limit θ under the action of a rare earthquake and calculating an inter-storey lateral drift limit Δ;
step 5: calculating the rotational stiffness of a beam column connection and a column base connection;
step 6: calculating the angular drift limits of the beam column connection and the column base connection according to a force method or a drift method;
step 7: designing the section size of a C-type energy dissipation steel plate;
step 8: calculating an allowable bending moment of a column bottom and an allowable bending moment of the beam column connection under the action of the rare earthquake;
step 9: calculating an axial force of an anchor rod when the angular drift limits are reached;
step 10: calculating the axial force of a beam column and the local pressure of each flange when the angular drift limits are reached;
step 11: conducting strength checking, stability checking and local pressure checking;
step 12: checking self-centering capability.

2. The connection design method for the lateral resisting system of the self-centering steel frame according to claim 1, wherein in step 1, the dimension parameters of components of the steel frame comprise section sizes and heights of a steel column and a steel beam, and the material characteristics comprise sectional inertia moment I, elastic modulus E and yield strength f_{y} of steel.

3. The connection design method for the lateral resisting system of the self-centering steel frame according to claim 1, wherein in step 3, the performance targets of the connections comprise prepressure applied by the anchor rod and prepressure applied by the beam column connection.

4. The connection design method for the lateral resisting system of the self-centering steel frame according to claim 1, wherein in step 6, the angular drift limits of the beam column connection and the column base connection are calculated based on the rotational stiffness of the beam column connection and the column base connection of step 5.

5. The connection design method for the lateral resisting system of the self-centering steel frame according to claim 1, wherein in step 7, the proportion of the bending moment bearing capacity provided by a disc spring in the bending capacity of the whole section is φ_{des}, and the proportion of the bending moment bearing capacity provided by the C-type energy dissipation steel plate is (1−φ_{des}), so as to design the section size of the C-type energy dissipation steel plate.

6. The connection design method for the lateral resisting system of the self-centering steel frame according to claim 1, wherein in step 8, the allowable bending moment of the column bottom and the allowable bending moment of the beam column connection are calculated according to a column axial force, an inter-storey horizontal force, anchor rod prepressure, disc spring deformation force and the angular drift limits.

7. The connection design method for the lateral resisting system of the self-centering steel frame according to claim 1, wherein in step 9, the axial force of the anchor rod at each connection under the action of the rare earthquake is calculated according to the angular drift limits.

8. The connection design method for the lateral resisting system of the self-centering steel frame according to claim 1, wherein in step 10, the moment of a rotation point is taken to obtain the equivalent axial force of the beam column when the angular drift limits are reached, and the local pressure of each flange is obtained through equilibrium conditions.

9. The connection design method for the lateral resisting system of the self-centering steel frame according to claim 1, wherein in step 11, if the checking meets the requirements, the self-centering capability can be checked.

10. The connection design method for the lateral resisting system of the self-centering steel frame according to claim 1, wherein in step 12, if the requirements cannot be met, φ_{des} is adjusted to reduce the section size of the C-type energy dissipation steel plate or increase the prestress of the disc spring, and the calculation is repeated until the requirements of self-centering are met.
